(19) United States
(12) Patent Application Publication
(10) Pub. No.: US 2019/0143477 A1
(43) Pub. Date: May 16, 2019

(54) APPARATUS AND METHOD FOR PLANARIZING SUBSTRATE

(71) Applicant: EBARA CORPORATION, Tokyo (JP)

(72) Inventors: Erina BABA, Tokyo (JP); Itsuki KOBATA, Tokyo (JP)

(21) Appl. No.: 16/185,773

(22) Filed: Nov. 9, 2018

(30) Foreign Application Priority Data
Nov. 13, 2017 (JP) 2017-218563

(51) Int. Cl. B24B 37/04; H01L 21/306; H01L 21/67; B24B 37/32; B24B 57/02

(52) U.S. Cl. CPC B24B 37/04; H01L 21/30625; B24B 57/02; B24B 37/32; H01L 21/67023

(57) ABSTRACT

An even step elimination performance is obtained even when steps of various dimensions exist which are caused due to pattern structures existing in a chip or film forming methods. A planarizing apparatus is provided which is configured to planarize a surface of a substrate, and this planarizing apparatus includes a surface roughening unit configured to roughen a target processing surface of the substrate by use of roughening particles and a CMP unit configured to polish chemically and mechanically (CMP) the roughened target processing surface of the substrate.

### CROSS-REFERENCE TO RELATED APPLICATION

This application is based upon and claims the benefit of priority of the prior Japanese Patent Application No. 2017-218563, filed on Nov. 13, 2017, the entire contents of which are incorporated herein by reference.

### TECHNICAL FIELD

The present invention relates to an apparatus and method for planarizing a substrate.

### BACKGROUND

In recent years, processing apparatuses are used to perform various types of processing on processing target objects (for example, a substrate such as a semiconductor wafer or various types of films formed on a surface of a substrate). There is raised as an example of such a processing apparatus a chemical mechanical polishing (CMP) apparatus for polishing a processing target object. In a general CMP, a processing target object is pressed against a polishing pad, and the processing target object and the polishing pad are moved relatively while a polishing agent (a slurry) is supplied between the processing target object and the polishing pad to thereby polish a surface of the processing target object.

It is known that a removal rate of a CMP apparatus follows Preston's Law, and a removal rate is proportional to a polishing pressure. When a surface of a substrate, which constitutes a polishing target object, is uneven, since a contact pressure against a polishing pad becomes greater at a protruded portion than at a recessed portion, the removal rate becomes faster at the protruded portion than at the recessed portion. In the CMP apparatus, a step on the surface of the substrate is eliminated by use of the difference in removal rate between the protruded portion and the recessed portion to thereby realize the planarization of the substrate surface.

Here, chips of various designs are formed on a surface of a substrate before it is planarized using the CMP apparatus, and these chips include steps of various heights caused by pattern structure and film forming method, and dimensions of the steps (specifically, width and surface area of protruded portions) vary widely. FIG. 1 illustrates sectional views of CMP process which planarizes a substrate including wiring portions and Cu layer. FIG. 1A illustrates a state where a barrier metal 53 is deposited by use of a PVD, CVD, or ALD on a substrate WF in which wiring grooves 52 are formed on an insulation film 51, a Cu seed film is further deposited on an upper layer of the barrier metal 53 by use of a PVD method or the like, and thereafter, a Cu layer 54 is plated by use of an electro plating method or the like. In a normal CMP process, an excessive Cu layer 54 on the barrier metal 53 that is located at portions other than the wiring portions is polished away in a first process, for example. Further, although not illustrated, in a second process, the barrier metal 53 is polished away and the insulation film 51 that lies underneath the barrier metal 53 is slightly polished away, whereby Cu is allowed to remain only at the wiring portions. This completes the process of embedding Cu in the wiring portions. Here, as illustrated, steps are formed on a surface of the Cu layer 54 due to the wiring structures (wiring widths and densities) lying underneath the formed Cu layer 54 and the electro plating film forming conditions. Especially, at a potion where narrow wiring grooves are formed densely, large size of step height (a left-hand side's protruded portion in FIG. 1A) can be formed in electroplating. Then, when the surface of the substrate having the steps of various dimensions is polished using CMP, a polishing pressure exerted on recessed portions and protruded portions of the steps differs depending upon the height, width and area of the steps. This is because a difference in pressures exerted on the protruded portions and recessed portions of the steps is caused to differ by the elasticity of the polishing pad which contacts the protruded portions and the recessed portions of the steps. In Detail, at a step which has low step height or a large width or surface area, a difference in removal rate between the protruded portion and the recessed portion of the step becomes smaller, and the speed of step height reduction with respect to the polishing amount becomes smaller, too. Due to this, the Cu layer 54 tends to remain more at a portion where the speed of step height reduction is slower than at other portions (FIG. 1B) at the time the barrier metal 53 starts to expose. In these situations, in the event that the Cu layer 54 remains between wirings, this should cause a short circuit between these wirings, and in the event that the Cu layer remains on a portion other than the portion between the wirings, another step should be newly formed when a film is formed over such a portion. Thus, the remaining Cu layer 54 needs to be removed completely, and to make this happen, an excessive polishing is carried out intentionally. As a result of this intentional excessive polishing, however, not only Cu is polished away excessively, but also the barrier metal 53 between the wirings or even the insulation film 51 lying underneath the barrier metal 53 is polished away at the wiring portions where a little or no excessive Cu remains. This causes dishing or erosion at the wiring portions after CMP is completed (FIG. 1C). The dishing and erosion affect largely to the variation in sectional area of the wirings and the performance of a device.

Although what has been described above is the example of the embedding process of the Cu wiring by use of CMP, in planarizing processes using the other methods, too, steps of various dimensions exist which are caused due to pattern structures within a chip or film forming methods at prior film forming stages, and the difference in dimension of the steps causes an uneven planarization performance. Thus, it has been desired that an even planarization performance is realized irrespective of a difference in dimension of steps.

### CITATION LIST

### Patent Literature

PTL 1: JP-2005-150171 A

### SUMMARY

The present invention has been made in view of the situations described above, and an object of the present invention is to provide a planarizing apparatus and method which can obtain an even step eliminating performance even under a condition where steps of various dimensions exist which are caused due to pattern structures existing within a chip or film forming methods.

[First Aspect] According to a first aspect, there is provided a planarizing apparatus for planarizing a surface of a substrate, including a surface roughening unit configured to roughen a target processing surface of the substrate by use of roughening particles, and a chemical mechanical polishing (CMP) unit configured to polish chemically and mechanically the roughened target processing surface of the substrate.

[Second Aspect] According to a second aspect, in the planarizing apparatus of the first aspect, the surface roughening unit includes a pad which is larger in dimension than the substrate, a table configured to hold the pad and capable of moving relative to the substrate, a substrate holding head configured to hold the substrate with the target processing surface of the substrate directed towards the pad and capable of moving relative to the pad while pressing the substrate against the pad, a first supply nozzle configured to supply a liquid containing roughening particles to the pad while roughening the target processing surface of the substrate, a second supply nozzle configured to supply a cleaning liquid for cleaning the substrate and the pad after roughening the target processing surface of the substrate, and a conditioner configured to condition a surface of the pad.

[Third Aspect] According to a third aspect, in the planarizing apparatus of the first aspect, the surface roughening unit includes a pad which is larger in dimension than the substrate and which contains roughening particles, a table configured to hold the pad and capable of moving relative to the substrate, a substrate holding head configured to hold the substrate with the target processing surface of the substrate directed towards the pad and capable of moving relative to the pad while pressing the substrate against the pad, a first supply nozzle configured to supply a liquid to the pad while roughening the target processing surface of the substrate, a second supply nozzle configured to supply a cleaning liquid for cleaning the substrate and the pad after roughening the target processing surface of the substrate, and a conditioner configured to condition a surface of the pad.

[Fourth Aspect] According to a fourth aspect, in the planarizing apparatus of the first aspect, the surface roughening unit includes a pad which is smaller in dimension than the substrate, a table configured to hold the substrate and capable of moving relative to the substrate, a holding head configured to hold the pad with the pad directed towards the substrate and capable of moving relative to the pad while pressing the pad against the substrate, an arm configured to oscillate the holding head on the substrate in a direction parallel to a plane of the substrate, a first supply nozzle configured to supply a liquid containing roughening particles to the substrate while roughening the target processing surface of the substrate, a second supply nozzle configured to supply a cleaning liquid to the substrate after roughening the target processing surface of the substrate, and a conditioner configured to condition a surface of the pad.

[Fifth Aspect] According to a fifth aspect, in the planarizing apparatus of the first aspect, the surface roughening unit includes a pad which is smaller in dimension than the substrate and which contains roughening particles, a table configured to hold the substrate and capable of moving relative to the pad, a holding head configured to hold the pad with the pad directed towards the substrate and capable of moving relative to the substrate while pressing the pad against the substrate, an arm configured to oscillate the holding head on the substrate in a direction parallel to a plane of the substrate, a first supply nozzle configured to supply a liquid to the substrate while roughening the target processing surface of the substrate, a second supply nozzle configured to supply a cleaning liquid for cleaning the substrate and the pad after roughening the target processing surface of the substrate, and a conditioner configured to condition a surface of the pad.

[Sixth Aspect] According to a sixth aspect, in the planarizing apparatus of the first aspect, the surface roughening unit includes a high-pressure supply nozzle configured to supply a liquid containing the roughening particles towards the substrate under a high pressure, a table configured to hold the substrate and capable of moving relative to the high-pressure supply nozzle, an arm configured to oscillate the high-pressure supply nozzle in a direction parallel to a plane of the substrate, and a supply nozzle configured to supply a cleaning liquid to the substrate after roughening the target processing surface of the substrate.

[Seventh Aspect] According to a seventh aspect, in the planarizing apparatus of any one of the first to sixth aspects, the relative movement includes at least one of a rotational movement, a straight-line movement, a scrolling movement and a combination of the rotational movement and the straight-line movement.

[Eighth Aspect] According to an eighth aspect, there is provided a planarizing apparatus for planarizing a surface of a substrate, including a CMP unit configured to perform Chemical Mechanical Polishing (CMP) of the substrate, a cleaning unit configured to clean the substrate, a drying unit configured to dry the substrate, and a transport mechanism configured to transport the substrate among the CMP unit, the cleaning unit and the drying unit, wherein the CMP unit includes a first supply nozzle configured to supply a liquid containing roughening particles, and a second supply nozzle configured to supply a CMP slurry.

[Ninth Aspect] According to a ninth aspect, in the planarizing apparatus in the eighth aspect, the CMP unit includes a pad which is larger in dimension than the substrate, a table configured to hold the pad and capable of moving relative to the substrate, a substrate holding head configured to hold the substrate with a target processing surface of the substrate directed towards the pad and capable of moving relative to the pad while pressing the substrate against the pad, a third supply nozzle configured to supply a cleaning liquid to the pad, and a conditioner configured to condition a surface of the pad, and the first supply nozzle is configured to supply the liquid containing roughening particles onto the pad, and the second supply nozzle is configured to supply the CMP slurry onto the pad.

[Tenth Aspect] According to a tenth aspect, in the planarizing apparatus in the eighth aspect, the CMP unit includes a pad which is smaller in dimension than the substrate, a table configured to hold the substrate and capable of moving relative to the pad, a holding head configured to hold the pad with the pad directed towards the substrate and capable of moving relative to the substrate while pressing the pad against the substrate, an arm configured to oscillate the holding head on the substrate in a direction parallel to a plane of the substrate, a third supply nozzle configured to supply a cleaning liquid to the substrate, and a conditioner configured to condition a surface of the pad, and the first supply nozzle is configured to supply the liquid containing roughening particles to the substrate, and the second supply nozzle is configured to supply the CMP slurry to the substrate.

[Eleventh Aspect] According to an eleventh aspect, in the planarizing apparatus in any one of the first to tenth aspects, an average particle diameter of the roughening particles is 100 nm or smaller.

[Twelfth Aspect] According to a twelfth aspect, in the planarizing apparatus in any one of the first to eleventh aspects, the roughening particles include particles of at least one particle selected from a group of diamond, SiC, CBN, SiO₂, CeO₂, and Al₂O₃.

[Thirteenth Aspect] According to a thirteenth aspect, there is provided a method for planarizing a substrate including a surface roughening step of roughening a target processing surface of the substrate using roughening particles, and a CMP step of performing Chemical Mechanical Polishing (CMP) of the roughened target processing surface of the substrate.

[Fourteenth Aspect] According to a fourteenth aspect, in the method of the thirteenth aspect, in the surface roughening step, a height of an unevenness formed on the target processing surface of the substrate as a result of roughening the target processing surface is 80% or smaller of a largest initial step existing on the target processing surface of the substrate before the target processing surface is roughened, and an average pitch of the unevenness formed on the target processing surface of the substrate as a result of roughening the target processing surface is 100 μm or smaller.

[Fifteenth Aspect] According to a fifteenth aspect, in the method of the thirteenth or fourteenth aspect, the surface roughening step includes a step of supplying a liquid containing roughening particle onto a pad which is larger in dimension than the substrate, and a step of moving the pad and the substrate relatively with the pad and the target processing surface of the substrate pressing against each other.

[Sixteenth Aspect] According to a sixteenth aspect, in the method of the thirteenth or fourteenth aspect, the surface roughening step includes a step of supplying a liquid containing roughening particle onto the substrate, and a step of moving a pad which is smaller in dimension than the substrate and the substrate relatively with the pad pressing against the substrate.

[Seventeenth Aspect] According to a seventeenth aspect, in the method of the thirteenth or fourteenth aspect, the surface roughening step includes a step of moving a pad which is larger in dimension than the substrate and to which roughening particles are fixed and the substrate relative to each other with the pad pressing against the substrate.

[Eighteenth Aspect] According to an eighteenth aspect, in the method of the thirteenth or fourteenth aspect, the surface roughening step includes a step of moving a pad which is smaller in dimension than the substrate and to which roughening particles are fixed and the substrate relative to each other with the pad pressing against the substrate, and a step of oscillating the pad on the substrate in a direction parallel to a plane of the substrate.

[Nineteenth Aspect] According to a nineteenth aspect, in the method of the thirteenth or fourteenth aspect, the surface roughening step includes a step of supplying a liquid containing roughening particles from a high-pressure supply nozzle towards the substrate under a high pressure, a step of moving the substrate relative to the high-pressure supply nozzle, and a step of oscillating the high-pressure supply nozzle in a direction parallel to a plane of the substrate.

[Twentieth Aspect] According to a twentieth aspect, in the method of any one of the thirteenth to nineteenth aspects, an average particle diameter of the roughening particles is 100 nm or smaller.

[Twenty-first Aspect] According to a twenty-first aspect, in the method of any one of the thirteenth to twentieth aspects, the roughening particles include particles of at least one selected from a group of diamond, SiC, CBN, SiO₂, CeO₂, and Al₂O₃.

[Twenty-second Aspect] According to a twenty-second aspect, in the method of any one of the fifteenth to twenty-first aspects, the relative movement includes at least one of a rotational movement, a straight-line movement, a scrolling movement and a combination of the rotational movement and the straight-line movement.

[Twenty-third Aspect] According to a twenty-third aspect, in the method according to any one of the thirteenth to twenty-second aspects, the surface roughening step is executed by a surface roughening unit, and the CMP step is executed by a CMP unit, and including a step of transporting the substrate roughened by the surface roughening unit to the CMP unit.

[Twenty-fourth Aspect] According to a twenty-fourth aspect, in the method of any one of the thirteenth to twenty-second aspects, the method includes a step of cleaning the roughened target processing surface of the substrate between the surface roughening step and the CMP step.

### BRIEF DESCRIPTION OF DRAWINGS

FIGS. 1A, B and C are sectional views illustrating steps of CMP process planarizing a substrate in which a Cu layer is formed on a substrate surface including a wiring portion,

FIG. 2 is a plan view illustrating a planarizing apparatus according to an embodiment,

FIG. 3 is a perspective view illustrating a surface roughening unit according to an embodiment,

FIG. 4 is a side view schematically illustrating a table according to an embodiment in which a Peltier device is provided in an interior as a cooling mechanism,

FIG. 5 is a side view schematically illustrating a table according to an embodiment which includes a cooling mechanism employing a cooling fluid,

FIG. 6 is a side view schematically illustrating a planarizing apparatus according to an embodiment,

FIG. 7 is a side view schematically illustrating a surface roughening unit according to an embodiment,

FIG. 8 is a perspective view schematically illustrating a surface roughening unit according to an embodiment,

FIG. 9 is a side view schematically illustrating a surface roughening unit according to an embodiment,

FIG. 10 is a side view schematically illustrating a surface roughening unit according to an embodiment,

FIG. 11 is a top view schematically illustrating a planarizing apparatus according to an embodiment,

FIGS. 12A, B and C depict processes followed when planarizing a substrate in which a Cu layer is formed on a substrate surface including wiring portions according to an embodiment,

FIG. 13 is a flow chart illustrating a method for planarizing a substrate surface according to an embodiment,

FIG. 14 is a flow chart illustrating a method for planarizing a substrate surface according to an embodiment, and

FIG. 15 is a side view schematically illustrating a planarizing apparatus according to an embodiment.

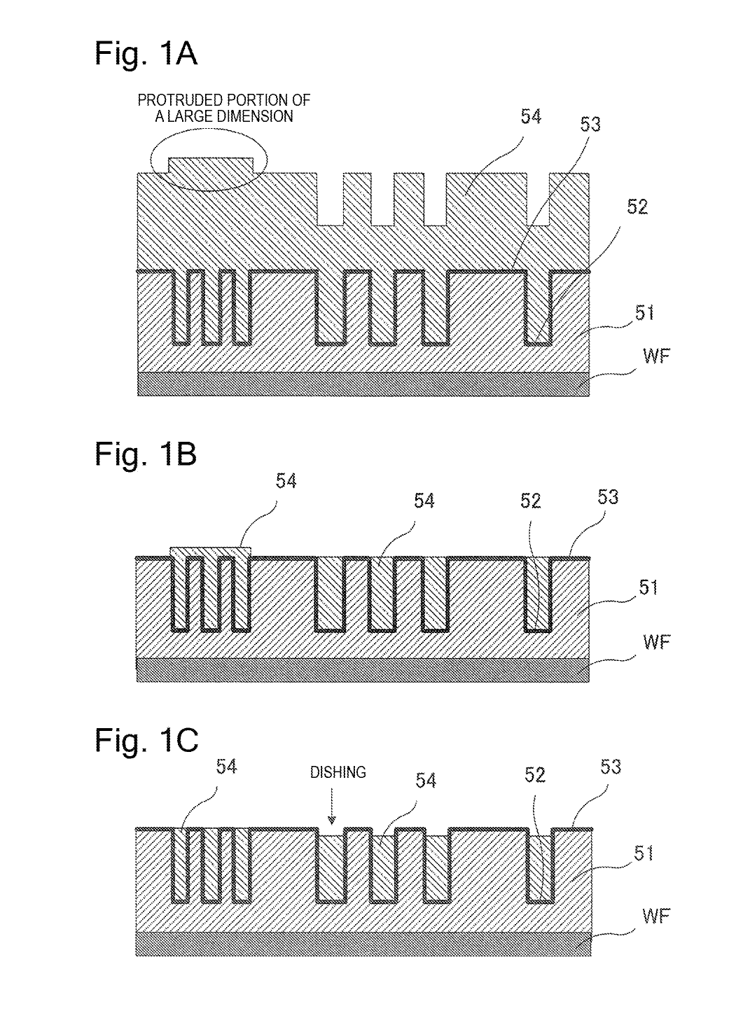

### DETAILED DESCRIPTION

Hereinafter, referring to accompanying drawings, embodiments of a planarizing apparatus and a planarizing method for planarizing a surface of a substrate according to the present invention will be described. In the accompanying drawings, like or similar reference numerals will be given to like or similar elements so that those like or similar elements do not have to be described repeatedly, and hence, the repeated description thereof will be omitted from time to time. Characteristics described in embodiments are applicable commonly among the embodiments, as long as the characteristics do not contradict to one another.

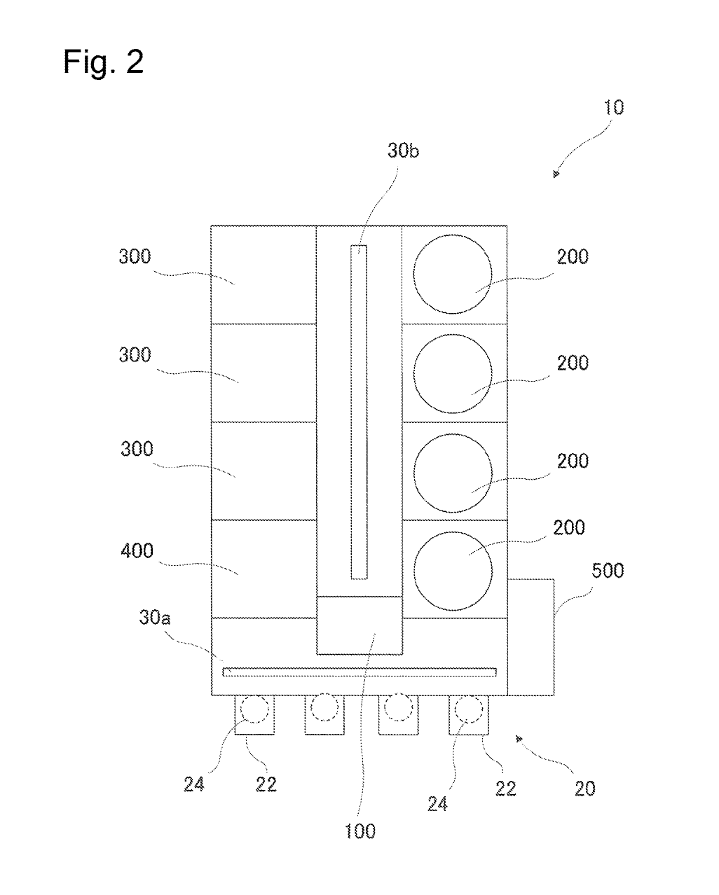

FIG. 2 is a plan view illustrating a planarizing apparatus 10 according to an embodiment. As illustrated in FIG. 2, the planarizing apparatus 10 includes a loading/unloading unit 20, a surface roughening unit 100, a polishing unit 200, a cleaning unit 300, and a drying unit 400. The planarizing apparatus 10 also includes a control unit 500 configured to control respective operations of the loading/unloading unit 20, the surface roughening unit 100, the polishing unit 200, the cleaning unit 300, and the drying unit 400.

The loading/unloading unit 20 constitutes a unit configured not only to transfer a substrate WF waiting for surface roughening to the surface roughening unit 100 but also to receive the substrate that has been surface roughened, polished, cleaned, and dried from the drying unit 400. The loading/unloading unit 20 includes a plurality of (four in this embodiment) front loading portions 22. A cassette or front-opening unified pod (FOUP) 24 for storing substrates is installed in each of the front loading portions 22.

The planarizing apparatus 10 includes transport mechanisms 30a, 30b. The transport mechanism 30a picks up a substrate WF from the cassette or FOUP 24 and transfers it to the surface roughening unit 100. The transport mechanism 30a may include a mechanism configured to reverse the substrate WF depending on a form of surface roughening carried out by the surface roughening unit 100. The transport mechanism 30a receives the substrate WF that has been surface roughened from the drying unit 400 and transfers it to the FOUP 24. The transport mechanism 30b receives and transfers substrates WF among the surface roughening unit 100, the polishing unit 200, the cleaning unit 300 and the drying unit 400. The transport mechanism 30b may include a mechanism configured to reverse a substrate WF depending on forms of polishing and cleaning carried by the polishing unit 200 and the cleaning unit 300. Although not illustrate, the transport mechanisms 30a, 30b may be made up of a plurality of transport robots. Additionally, the transport mechanisms 30a, 30b can be configured arbitrarily, and hence, the transport mechanisms 30a, 30b can be made up of movable robots capable of holding and releasing a substrate WF.

Although details will be described later, the surface roughening unit 100 constitutes a unit configured to roughen a target processing surface of a substrate WF before the substrate WF is polished at the polishing unit 200.

The polishing unit 200 constitutes a unit configured to polish the roughened target processing surface of the substrate WF. In the embodiment illustrated in FIG. 2, the planarizing apparatus 10 includes four polishing units 200. The four polishing units 200 can have the same configuration. In an embodiment, the polishing unit can be a CMP unit of an arbitrary configuration.

The cleaning unit 300 constitutes a unit configured to clean the substrate WF that has been surface roughened by the surface roughening unit 100 or the substrate WF that has been polished by the polishing unit 200. In the embodiment illustrated in FIG. 2, although three cleaning units 300 are provided, an arbitrary number of cleaning units 300 can be provided. The plurality of cleaning units 300 may have the same or different configurations.

The drying unit 400 constitutes a unit configured to dry the substrate WF which has been cleaned by the cleaning unit 300. The drying unit 400 can adopt an arbitrary configuration.

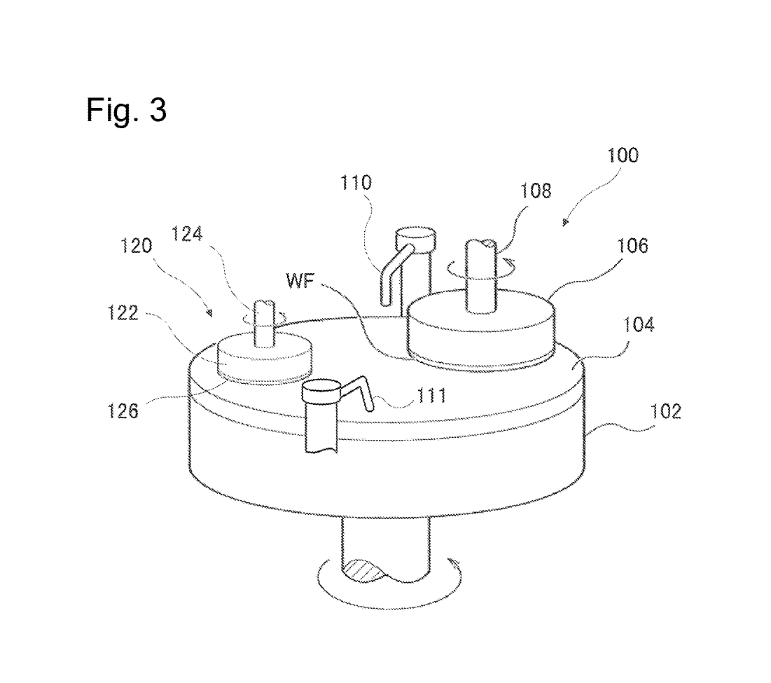

Hereinafter, embodiments of the surface roughening unit 100 will be described which can be adopted for the planarizing apparatus 10. FIG. 3 is a perspective view illustrating a surface roughening unit 100 of an embodiment. The surface roughening unit 100 illustrated in FIG. 3 includes a table 102 including a flat upper surface. In this embodiment, the table 102 can be rotated in a direction indicated by an arrow in FIG. 3 by a drive mechanism such as a motor, not illustrated; however, the table 102 may be configured to move in other forms of movement such as a straight-line movement, a scrolling movement, and a combination of the straight-line movement and the rotational movement, for example. Here, the straight-line movement includes a straight-line reciprocating movement, and the rotational movement includes a rotational movement about its own axis as illustrated in FIG. 3, a turning movement, an angular rotational movement and an eccentric rotational movement. The combination of the straight-line movement and the rotational movement includes, for example, a movement along an orbital elliptic course. A surface roughening pad 104 is affixed to the upper surface of the table 102. In the embodiment illustrated in FIG. 3, the surface roughening pad 104 is larger in dimension than a substrate WF to be surface roughened. In an embodiment, the surface roughening pad 104 can constitute a surface roughening pad having a diameter that is three times, at the most, larger than a diameter of the substrate WF. In this embodiment, as will be described later, the substrate WF and the surface roughening pad 104 are caused to move relative to each other when the substrate WF is surface roughened; however, since a relative speed between the substrate WF and the surface roughening pad 104 can be made faster as the diameter of the surface roughening pad 104 is increased further, a processing speed at which the substrate WF is surface roughened is increased by increasing the surface roughening speed.

The surface roughening unit 100 includes a holding head 106 configured to hold the substrate WF. The holding head 106 is connected to a rotatable shaft 108. The shaft 108 can be rotated together with the holding head 106 as indicated by an arrow illustrated in FIG. 3 by a drive mechanism, not illustrated. The substrate WF is supported securely on a lower surface of the holding head 106 through vacuum chuck. The holding head 106 is configured to move in a direction normal to the surface of the surface roughening pad 104. Additionally, the holding head 106 is connected to an arm 109 (not illustrated in FIG. 3) which can move in the plane of the table 102, for example, in a radial direction of the table 102. The surface roughening unit 100 can roughen a surface of the substrate WF by supplying a liquid containing roughening particles onto the surface roughening pad 104 and moving the holding head 106 within a plane of the table 102 with the substrate WF pressed against the surface roughening pad 104 by the holding head 106 while rotating the table 102 and the holding head 106 individually.

A similar pad to a polishing pad used in CMP can be used as the surface roughening pad 104. Here, the surface roughening pad 104 is formed, for example, of a hard pad of an expanded poly urethane system, a soft pad of a suede system, or sponge. A type of the surface roughening pad 104 should be selected as required according to a material a target processing surface of the substrate WF or type of roughening particles. For example, in a case where a target processing surface of the substrate WF is made of a material of a small mechanical strength such as a Cu or Low-k film or the hardness of roughening particles described later is great, in roughening the target processing surface, since the target processing surface may be roughened more than required, a pad of a low hardness or rigidity may be selected. On the other hand, when a projecting portion on the surface of the substrate WF is roughened for preference, a contact of the surface roughening pad 104 with the substrate WF needs to be controlled. To make this happen, it is preferable to have a wide selectivity of a contact pressure at which the surface roughening pad 104 contacts uneven portions on a surface of a removal material of the substrate WF. For example, in a case where only protruded portions of uneven portions existing on the initial target processing surface of the substrate WF are attempted to be roughened selectively, a roughening pad of a high hardness or rigidity may be selected as the surface roughening pad 104. Additionally, the surface roughening pad 104 may be made up of a structure in which multiple pads are stacked on one another. For example, the surface roughening pad 104 may adopt a two-layer structure in which a surface which is brought into contact with the target processing surface of the substrate WF is made up of a pad of a high hardness or rigidity, while a lower layer is made up of a pad of a low hardness or rigidity. By doing so, the rigidity of the surface roughening pad 104 can be controlled.

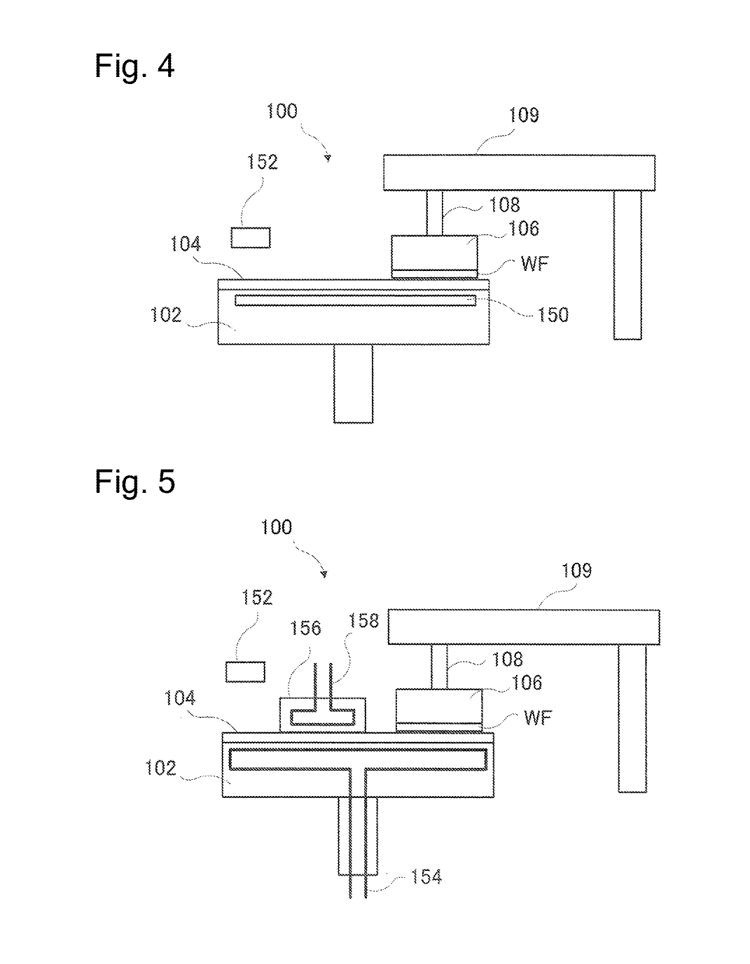

As a method for controlling the rigidity of the surface roughening pad 104, the surface of the surface roughening pad 104 can be cooled by a cooling mechanism, so that the rigidity of the surface of the surface roughening pad 104 can be increased, thereby making it possible to enhance selectivity of the contact pressure of the surface roughening pad 104. As the cooling mechanism, for example, a Peltier device may be provided in an interior of the table 102 to which the surface roughening pad 104 is affixed. FIG. 4 is a side view schematically illustrating a table 102 having a Peltier device 150 provided in an interior thereof as a cooling mechanism. A surface roughening unit 100 illustrated in FIG. 4 includes a thermometer 152 such as a radiation thermometer, for example. The thermometer 152 is configured to measure a temperature on the surface of the surface roughening pad 104. As an example, a current supplied to the Peltier device 150 can be controlled based on a temperature of the surface roughening pad 104 measured by the thermometer 152 so that the temperature on the surface of the surface roughening pad 104 is controlled to a predetermined temperature.

Additionally, in an embodiment, a cooling fluid can also be used as a cooling mechanism for cooling the surface roughening pad 104. FIG. 5 is a side view schematically illustrating a table 102 including a cooling mechanism which utilizes a cooling fluid. The table 102 illustrated in FIG. 5 includes a fluid passageway 154 through which a cooling fluid is passed through an interior of the table 102. The temperature of the surface roughening pad 104 can be controlled by controlling the temperature of a cooling fluid passing through the fluid passageway 154. In addition, the cooling mechanism illustrated in FIG. 5 includes a pad contact member 156 configured to be brought into contact with the surface of the surface roughening pad 04 and a liquid supply mechanism 158 through which a temperature controlled liquid is supplied into the pad contact member 156. The liquid supply mechanism 158 can constitute a passageway through which the temperature controlled liquid passes. As a liquid used in the liquid supply mechanism 158, hot water and cold water can be used, whereby temperatures and supply amounts of the hot water and the cold water which are passed to the pad contact member 156 are controlled, so that the pad contact member 156 and the surface roughening pad 104 can be controlled to a predetermined temperature. In the embodiment illustrated in FIG. 5, too, a thermometer 152 is provided. The surface roughening pad 104 can be controlled to a predetermined temperature by controlling the temperature and/or the flow rate of a cooling fluid which passes through the fluid passageway 154 and the temperature and/or flow rate of a liquid which passes through the liquid supply mechanism 158 based on a temperature of the surface roughening pad 104 measured by the thermometer 152. Although the cooling mechanism illustrated in FIG. 5 is described as being made up of the two cooling mechanisms, that is, the cooling mechanism utilizing the fluid passageway 154 which passes through an interior of the table 102 and the cooling mechanism utilizing the pad contact member 156 configured to be brought into contact with the surface roughening pad 104, only either of the two cooling mechanisms may be provided. In FIGS. 4, 5, for the purpose of clarifying the illustration, a roughening particle supply nozzle 110 and a conditioner 120 are omitted; however, the surface roughening unit 100 can include them.

Grooves including, for example, concentric grooves, XY grooves formed vertically and horizontally, spiral grooves, and radial grooves may be formed on the surface of the surface roughening pad 104. Providing such grooves facilitates a uniform supply of a liquid containing roughening particles between the substrate WF and the surface roughening pad 104, which will be described later, or a discharge of process products generated during surface roughening.

In addition, as to pressures applied during surface roughening, a contact pressure at which the substrate WF and the surface roughening pad 104 are brought into contact with each other should preferably be small, and the contact pressure should preferably be one psi or smaller and more preferably be 0.1 psi or smaller. As a method for forcing the substrate WF against the surface roughening pad 104, the substrate WF held by the holding head 106 may be pressed against the surface roughening pad 104 by a drive mechanism such as an air cylinder or a ball screw. As a different embodiment, although not illustrated, the substrate WF may be pressed against the surface roughening pad 104 by use of an air bag provided behind the substrate WF into which air corresponding to the contact pressure is supplied after the holding head 106 is caused to approach the surface roughening pad 104. The air bag may be divided into a plurality of regions so that pressures in the divided regions are controlled. Using this method enables the contact pressure at which the substrate WF is pressed against the surface roughening pad 104 to be changed, thereby making it possible to control the height of an unevenness formed during surface roughening.

In the embodiment illustrated in FIG. 3, the surface roughening unit 100 includes a roughening particle supply nozzle 110 configured to supply a liquid in which roughening particles for roughening the target processing surface of the substrate WF are dispersed on to the surface roughening pad 104. In an embodiment, the roughening particles supply nozzle 110 can constitute a roughening particle supply nozzle configured to supply roughening particles to a fixed constant position on the surface roughening pad 104 on the table 102. In another embodiment, the roughening particles supply nozzle 110 can be configured capable of moving and to supply roughening particles to an arbitrary position on the surface roughening pad 104 on the table. For example, by moving the roughening particles supply nozzle 110 in synchronism with the holding head 106, a liquid in which roughening particles are dispersed can be supplied between the substrate WF and the surface roughening pad 104 efficiently.

Here, sizes, types and concentrations of roughening particles for use in roughening the surface of the substrate WF can be selected based on sizes of initial stepson a removal target layer and a thickness and type of the layer. A type of roughening particles can contain at least one of, for example, diamond, silicon carbide (SiC), cubic boron nitride (CBN), silicon dioxide (SiO₂), cerium oxide (CeO₂), and aluminum oxide (Al₂O₃). Roughening particles can have a particle size in the range from 100 nm to about several hundreds of nanometers. For example, a large step height of the order of 100 nm may exist on a surface of a substrate WF before it is polished through CMP. In this case, the surface of the substrate WF is desirably surface roughened to an unevenness of a height of 10 nm to several tens of nanometers. Roughening particles whose size falls in the range of particle sizes described above are desirably used so that an unevenness formed on the surface of the substrate WF when it is surface roughened is not polished away to such a depth that a wiring structure of the substrate is reached. In addition, when a substrate WF having small initial steps is surface roughened, the substrate WF is desirably surface roughened so that an unevenness formed on the surface of the substrate WF is reduced to 10 nm or smaller. In this case, roughening particles having a particle size in the range from 10 nm to several tens of nanometers should desirably be used. The concentration of roughening particles then should be less than 10 wt % and be preferably less than 1 wt %. This is because when the concentration of roughening particles becomes great, although the surface roughening speed becomes faster, whereas the target processing surface of the substrate WF itself is polished away. A pure water (DIW: De-Ionized Water) may be used as a liquid in which roughening particles are suspended; however, a pH control using a pH control agent may be performed as required depending on the property of the target processing surface of the substrate WF. For roughening particles having a high agglomeration property such as CeO₂, for example, the agglomeration of roughening particles may be suppressed by adding a dispersant. When surface roughening only protruded portions of steps existing initially on the target processing surface of the substrate WF selectively, to protect recessed portions, a protective component may be added. This enables the selectivity of protruded portions on a step to be controlled when surface roughening such protruded portions.

In addition, in the embodiment illustrated in FIG. 3, the surface roughening unit 100 includes a cleaning liquid supply nozzle 111 configured to supply a cleaning liquid for cleaning the substrate WF and the surface roughening pad 104 after the target processing surface of the substrate WF is surface roughened. This enables a removal of the liquid containing roughening particles which remains on the target processing surface of the substrate WF and the surface roughening pad 104 and process products generated during surface roughening. Although DIW may be used as a cleaning liquid, a chemical may be supplied as a cleaning liquid as required depending on the type of roughening particles. The cleaning liquid supply nozzle 111 may be configured to supply the cleaning liquid to a constant position on the surface roughening pad 104. Alternatively, the cleaning liquid supply nozzle 111 may be configured capable of moving so as to supply the cleaning liquid to an arbitrary position on the surface roughening pad 104. Although not illustrating, the cleaning liquid may be supplied by use of a high-pressure nozzle.

The surface roughening unit 100 illustrated in FIG. 3 includes a conditioner 120 configured to condition the surface roughening pad 104. The conditioner 120 includes a conditioning head 122. The conditioning head 122 is connected to a rotatable shaft 124. The shaft 124 can be rotated together with the conditioning head 122 by a drive mechanism, not illustrated, as illustrated in FIG. 3. A conditioning pad 126 is attached to a lower surface of the conditioning head 122. Here, the conditioning pad 126 may be such that diamonds are fixed by a fixing layer such as an Ni electro deposit layer, or a resin brush may be fixed in place. The conditioning head 122 is configured to move in a direction normal to the surface of the surface roughening pad 104. The conditioning head 122 is also configured to move within a plane of the table 102, that is, in a radial direction of the table 102, for example. The surface roughening unit 100 can condition the surface roughening pad 104 by forcing the conditioning pad 126 of the conditioning head 122 against the surface roughening pad 104 at a predetermined pressure by use of a forcing mechanism such as an air cylinder or a ball screw and moving the conditioning head 122 within the plane of the table 102 while rotating the table 102 and the conditioning head 122 individually. The conditioning may be executed at the same time as the substrate WF is surface roughened, or the conditioning may be executed after the current substrate WF is surface roughened and before the next substrate WF is surface roughened. This enables the surface condition of the surface roughening pad 104 to be maintained in surface roughening, whereby the surface roughening performance is stabilized. The surface of the surface roughening pad 104 may be smoothed more than when it is used as a polishing pad in CMP. In this case, a level at which the surface roughening pad 104 is smoothed can be 10 μm or smaller and can preferably be 1 μm or smaller. In this case, for example, a diameter of diamond on the conditioning pad 126 is reduced. Alternatively, a protruded amount of diamond from the fixing layer is reduced, whereby a machining amount of the surface roughening pad 104 can be reduced.

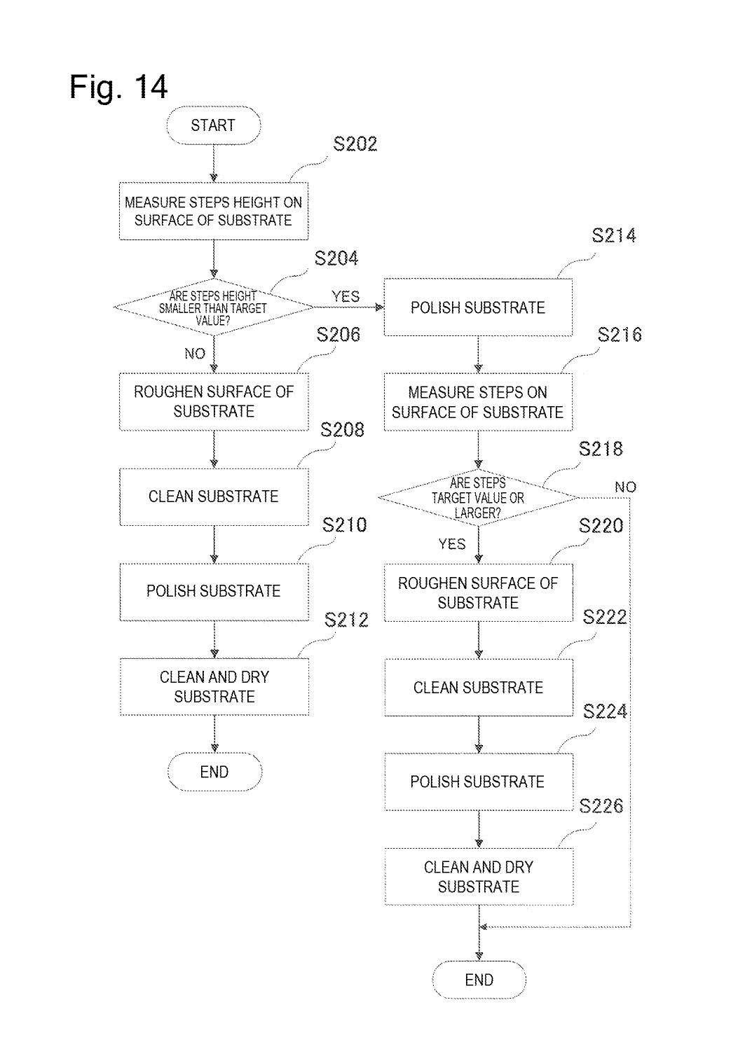

Although not illustrated in FIG. 3, the surface roughening unit 100 includes a controller. Various drive mechanisms and opening and closing valves of the various nozzles of the surface roughening unit 100 are connected to the controller, whereby the controller can control the operation of the surface roughening unit 100. The controller includes an operation module configured to process the results of measurements of steps, which will be described in FIG. 14, to determine whether or not the processed measurement results are less than a target value, for example. The controller is configured to control the surface roughening unit 100 based on the results of processing and determinations made by the operation module. The controller can be configured by installing a predetermined program in a general computer including a memory, a CPU, an input/output mechanism and the like.

Although not illustrated in FIG. 3, the surface roughening unit 100 may include a processing state detection module configured to determine an end of a processing in surface roughening. The processing state detection module may adopt a form in which light such as a laser beam is incident on a surface of a target processing film of a substrate WF to detect reflected light from the target processing film or a form in which a surface state of the substrate WF is detected by use of image recognition. In the former form, by making use of a fact that incident light is scattered on the surface of the target processing film of the substrate WF, which is now roughened, whereby the intensity of reflected right changes, the surface roughening ends at a point in time when the intensity of reflected light reaches a specific intensity. In the latter form, a change in tonality is detected, and the surface roughening ends at a point in time when a specific tonality is reached. In addition, as a form of detecting a processing state, a change in torque of a drive motor may be monitored during, for example, a rotational movement of the table 102 to which the pad is attached or a surface roughening head 134, which will be described later, a rotational movement of the holding head 106 which holds the substrate WF or a table 132, or a oscillating movement of the surface roughening head 134. This makes use of a fact that the contact and frictional state with the pad changes as the state of the target processing surface of the substrate WF changes as a result of the target processing surface being roughened. Here, the detection module is connected to a signal processing module configured to process signals of reflected light, tonality and torque detected by the detection module, and the controller ends the surface roughening based on the signals. The signal processing module configured to process signals detected by the detection module and the controller configured to control the various drive mechanisms and the opening and closing valves of the various nozzles may use the same hardware commonly or may use different hardware. When different hardware is used, hardware resources can be divided for the surface roughening of the substrate WF, the detection of the surface state of the substrate WF and the following signal processing, whereby the overall processing can be carried out at high speeds.

FIG. 7 is a side view schematically illustrating a surface roughening unit 100 according to an embodiment. The surface roughening unit 100 illustrated in FIG. 7 employs a surface roughening pad 104a affixed onto a table 102 to surface roughen a substrate WF held to a holding head 106. Here, in the surface roughening unit 100 illustrated in FIG. 7, roughening particles are fixed to the surface roughening pad 104a by a binder of resin material or the like. Due to this, in the surface roughening unit 100 according to this embodiment, a liquid containing roughening particles does not have to be supplied onto the surface roughening pad 104a as done in the embodiment illustrated in FIG. 3, and hence, the roughening particles supply nozzle 110 is unnecessary. Here, sizes, types and concentrations of roughening particles fixed to the surface roughening pad 104a can be selected based on sizes of initial steps on a removal target layer and a thickness and type of the layer of the substrate WF. A type of roughening particles can contain at least one of, for example, diamond, silicon carbide (SiC), cubic boron nitride (CBN), silicon dioxide (SiO₂), cerium oxide (CeO₂), and aluminum oxide (Al₂O₃). Roughening particles can have a particle size in the range from 100 nm to about several hundreds of nanometers. For example, a large step height of the order of 100 nm may exist on a surface of a substrate WF before it is polished through CMP. In this case, the surface of the substrate WF is desirably surface roughened to an unevenness of a height of 10 nm to several tens of nanometers. Roughening particles whose size falls in the range of particle sizes described above are desirably used so that an unevenness formed on the target processing surface of the substrate WF when it is surface roughened is not polished away to such a depth that a wiring structure of the substrate is reached. In addition, when a substrate WF having small initial steps is surface roughened, the substrate WF is desirably surface roughened so that an unevenness formed on the surface of the substrate WF is reduced to 10 nm or smaller. In this case, roughening particles having a particle size in the range from 10 nm to several tens of nanometers should desirably be used. The surface roughening unit 100 illustrated in FIG. 7 includes a liquid supply nozzle 112 configured to supply a liquid onto the surface roughening pad 104a while the target processing surface of the substrate WF is roughened or during surface roughening and a cleaning liquid supply nozzle 111 configured to supply a cleaning liquid. Although a liquid supplied during surface roughening may be pure water, a chemical in which a binder component is dissolved may be supplied. The liquid supply nozzle 112 may be configured to supply a liquid to a constant position on the surface roughening pad 104a, or the liquid supply nozzle 112 may be configured to move so as to supply a liquid to an arbitrary position on the surface roughening pad 104a. After surface roughening is completed, the cleaning liquid supply nozzle 111 supplies a cleaning liquid to remove the liquid containing roughening particles which remains on the target processing surface of the substrate WF and the pad 104a and process products generated during surface roughening.

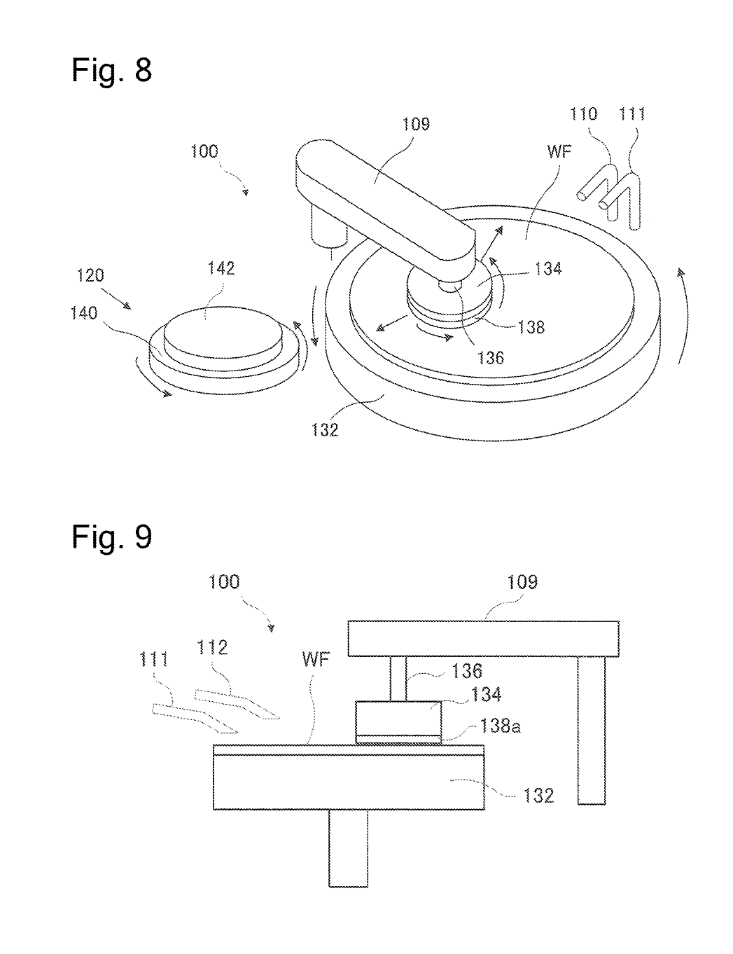

FIG. 8 is a perspective view schematically illustrating a surface roughening unit 100 according to an embodiment. The surface roughening unit 100 illustrated in FIG. 8 includes a table 132 including a flat upper surface. The table 132 can be rotated by a motor or the like, not illustrated. A substrate WF can be fixed to the upper surface of the table 132 through vacuum chuck or the like. A cushion material may be provided on a substrate WF fixing surface of the table 132. Due to this, the substrate WF is directly sucked via the table 132, whereas the substrate WF is sucked via the cushion material. The cushion material is formed of an elastic material such as, for example, polyurethane, nylon, fluororubber, silicone rubber and the like and is tightly secured to the table 132 via a viscous resin layer. Since the cushion material has elasticity, the cushion material not only prevents the wafer from being damaged but also mitigates the influence on the surface roughening of unevenness on the surface of the table 132 on the surface roughening.

The surface roughening unit 100 illustrated in FIG. 8 includes a surface roughening head 134. The surface roughening head 134 is coupled to a rotatable shaft 136. The shaft 136 can be rotated together with the surface roughening head 134 by a drive mechanism, not illustrated. A surface roughening pad 138 is attached to a lower surface of the surface roughening head 134. The shaft 136 is connected to an oscillating arm 109. In the embodiment illustrated in FIG. 8, the surface roughening pad 138 is smaller in dimension than a substrate WF which constitutes a processing target. For example, with a diameter ϕ of the substrate WF being 300 mm, a diameter ϕ of the surface roughening pad 138 is preferably 100 mm or smaller and is more preferably in the range from 60 to 100 mm. Since an area ratio with the substrate WF becomes smaller as the diameter of the surface roughening pad 138 becomes larger, a processing speed at which the substrate WF is processed is increased. On the contrary, uniformity of processing speeds within a target processing surface of the substrate WF is processed or roughened becomes better as the diameter of the surface roughening pad 138 becomes smaller. This is because a unit processing area becomes smaller, and as will be described later, this becomes advantageous in a form in which an overall surface of the substrate WF is processed or roughened by moving or oscillating relatively the surface roughening pad 138 within a plane of the substrate WF by the arm 109. The surface roughening head 134 is configured to move in a direction normal to the surface of the substrate WF on the table 132, whereby the surface roughening pad 138 can be pressed against the substrate WF at a predetermined pressure. Here, as a form of forcing the surface roughening pad 138 against the substrate WF, a form may be adopted in which the surface roughening pad 138 is pressed against the substrate WF by use of an air cylinder, a ball screw or the like. Alternatively, a form may be adopted in which although not illustrated, an air bag is disposed inside the surface roughening head 134, and air corresponding to a contact pressure is supplied into the air bag after the surface roughening head 134 is caused to approach the substrate WF, whereby the surface roughening pad 138 is pressed against the substrate WF. The air bag may be divided into multiple regions, and pressures at the divided regions may be controlled. The surface roughening head 134 is configured to move within the plane of the table 132, for example, in a radial direction of the table 132 by the arm 109. Here, as to a moving speed at which the surface roughening head 134 is moved by the arm 109, since an optimal moving speed distribution differs depending on rotational speeds of the substrate WF and the surface roughening head 134 and a moving distance of the surface roughening head 134, and therefore, it is desirable that the moving speed of the surface roughening head 134 can be changed within the plane of the substrate WF. As this occurs, as a form of changing the moving speed, for example, a form is desirable in which for example, an oscillating distance within the plane of the substrate WF is divided in a plurality of sections, and a moving speed can be set for each of the divided sections. The surface roughening unit 100 includes a roughening particle supply nozzle 110 as in the embodiment illustrated in FIG. 3. The surface roughening unit 100 can roughen the substrate WF by not only supplying a liquid containing roughening particles to the substrate WF but also forcing the surface roughening head 134 against the substrate WF and moving the surface roughening head 134 within the plane of the table 132 while rotating the table 132 and the surface roughening head 134 individually. The surface roughening pad 138 may be similar to the surface roughening pad 104 of the embodiment illustrated in FIG. 3 excluding the dimension of the surface roughening pad 138. The surface roughening unit 100 illustrated in FIG. 8 includes further a cleaning liquid supply nozzle 111 configured to supply a cleaning liquid onto the substrate WF. The cleaning liquid can be made up of pure water and/or a chemical. In addition, in the surface roughening unit 100 illustrated in FIG. 8, although a surface roughening liquid is supplied onto the substrate WF by a roughening particle supply nozzle 110, as a separate form, a form may be adopted in which a supply flow path is provided inside the surface roughening head 134, and the liquid containing roughening particles is supplied through a through hole provided within the surface roughening pad 138. By using this form, even when the surface roughening head 134 oscillates within the plane of the substrate WF, the liquid containing roughening particles can efficiently be supplied to a contact plane between the surface roughening pad 138 and the substrate WF.

The surface roughening unit 100 illustrated in FIG. 8 includes further a conditioner 120 configured to condition the surface roughening pad 138. The conditioner 120 includes a dressing table 140 and a dresser 142 placed on the dressing table 140. The dressing table 140 is configured to be rotated by a drive mechanism, not illustrated. The dresser 142 is formed of a diamond dresser, a brush dresser or a combination thereof. In the surface roughening unit 100 illustrated in FIG. 8, the arm 109 is turned to a position where the surface roughening pad 138 faces the dresser 142 when conditioning the surface roughening pad 138. The surface roughening unit 100 can condition the surface roughening pad 138 by forcing the surface roughening pad 138 against the dresser 142 while rotating both the surface roughening pad 138 and the dresser 142.

FIG. 9 is a side view schematically illustrating a surface roughening unit 100 according to an embodiment. As with the surface roughening unit 100 illustrated in FIG. 8, the surface roughening unit 100 illustrated in FIG. 9 is configured so as to roughen a surface or a target processing surface of a substrate WF by forcing a surface roughening pad 138a which is small in diameter against the substrate WF with the substrate WF held on a table 132 so as to be oriented upwards. In the surface roughening unit 100 illustrated in FIG. 9, however, roughening particles are fixed to the surface roughening pad 138a with a binder of a resin material, for example. Due to this, in the surface roughening unit 100 according to this embodiment, a liquid containing roughening particles does not have to be supplied onto the substrate WF, which is done in the embodiment illustrated in FIG. 8, and hence, the roughening particle supply nozzle 110 is unnecessary. The surface roughening unit 100 illustrated in FIG. 9 includes a liquid supply nozzle 112 configured to supply a liquid onto the substrate WF. Although a liquid supplied when the target processing surface of the substrate WF is roughened or during surface roughening may be pure water, a chemical in which a binder component is dissolved may be supplied. The liquid supply nozzle 112 may be configured to supply the liquid to a constant position on the substrate WF; however, the liquid supply nozzle 112 may be configured to move so as to supply the liquid to an arbitrary position on the substrate WF. After the target processing surface of the substrate WF is roughened, a cleaning liquid is supplied by a cleaning liquid supply nozzle 111, whereby the liquid containing roughening particles which remains on the target processing surface of the substrate WF and the surface roughening pad 104a and process products generated during the surface roughening are removed.

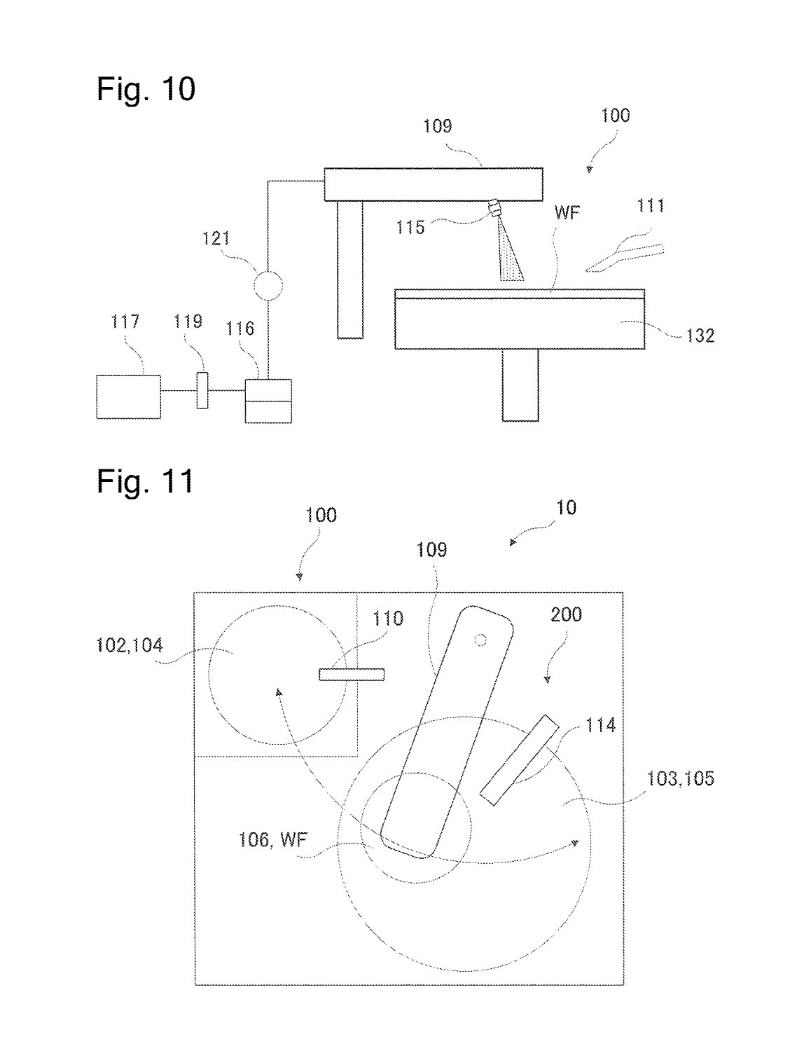

FIG. 10 is a side view schematically illustrating a surface roughening unit 100 according to an embodiment. As with the surface roughening units 100 illustrated in FIGS. 8, 9, the surface roughening unit 100 illustrated in FIG. 10 is configured to hold a substrate WF on a table 132 with the substrate WF directed upwards. In the surface roughening unit 100 according to the embodiment illustrated in FIG. 10, however, no surface roughening pad is used. In the surface roughening unit 100 illustrated in FIG. 10, a high-pressure supply nozzle 115 configured to supply a liquid containing roughening particles to a surface or a target processing surface of the substrate WF under a high pressure condition and attached to an arm 109 configured to oscillate parallel to the surface of the substrate WF. The high-pressure supply nozzle 115 is connected to a roughening particle supply tank 116. The roughening particle supply tank 116 is connected to a compressor 117, a regulator 119 and the like, whereby a liquid containing roughening particles can be sprayed from the high-pressure supply nozzle 115 to the surface of the substrate WF via a pressure gauge 121 under a pressure of, for example, 1 kgf/cm² to 10 kgf/cm². Here, sizes, types and concentrations of roughening particles can be selected based on initial step height on a removal target layer of the substrate WF and a thickness and type of the layer. A type of roughening particles can contain at least one of, for example, diamond, silicon carbide (SiC), cubic boron nitride (CBN), silicon dioxide (SiO₂), cerium oxide (CeO₂), and aluminum oxide (Al₂O₃). Roughening particles can have a particle size in the range from 100 nm to about several hundreds of nanometers. For example, a large step height of the order of 100 nm may exist on a surface of a substrate WF before it is polished through CMP. In this case, the surface of the substrate WF is desirably surface roughened to an unevenness of an order of about 10 nm to several tens of nanometers. Roughening particles whose size falls in the range of particle sizes described above are desirably used so that an unevenness formed on the surface of the substrate WF when it is surface roughened is not polished away to such a depth that a wiring structure of the substrate is reached. In addition, when a substrate WF having small initial step height is surface roughened, the substrate WF is desirably surface roughened so that an unevenness formed on the surface of the substrate WF is reduced to 10 nm or smaller. In this case, roughening particles having a particle size in the range from 10 nm to several tens of nanometers should desirably be used. A DIW may be used as a liquid in which roughening particles are suspended; however, a pH control using a pH control agent may be performed as required depending on the property of the target processing surface of the substrate WF. For roughening particles having a high agglomeration property such as CeO₂, for example, the agglomeration of roughening particles may be suppressed by adding a dispersant. When surface roughening only protruded portions of uneven portions existing initially on the target processing surface of the substrate WF selectively, to protect recessed portions, a protective component may be added. This enables the selectivity of protruded portions on an uneven portion to be controlled when surface roughening such protruded portions. For moving speed at which the high-pressure supply nozzle 115 by the arm 109, since an optimal distribution of moving speeds differs depending on the rotational speed of the substrate WF or the moving distance of the high-pressure supply nozzle 115, it is desirable that the moving speed of the high-pressure supply nozzle 115 within the plane of the substrate WF is variable. In this case, as a form of changing the moving speed, a form is desirably adopted in which the oscillating distance within the plane of the substrate WF is dived into a plurality of sections, so that a moving speed can be set for each of the divided sections. The surface roughening unit 100 illustrated in FIG. 10 includes a cleaning liquid supply nozzle 111 configured to supply a cleaning liquid onto the substrate WF after the surface roughening is completed. The cleaning liquid supply nozzle 111 may be configured to supply the liquid to a constant position on the substrate WF or may be configured to move so as to supply the liquid to an arbitrary position on the substrate WF.

FIG. 11 is a top view schematically illustrating a planarizing apparatus 10 according to an embodiment. The planarizing apparatus 10 illustrated in FIG. 11 includes a surface roughening unit 100 and a polishing unit 200 which are disposed within the same housing. The planarizing apparatus 10 illustrated in FIG. 11 includes a table 102 which is larger in dimension than a substrate WF and a surface roughening pad 104. The polishing unit 200 of the planarizing apparatus 10 is a CMP unit. The CMP unit includes a table 103 including a flat upper surface which is larger in dimension than the substrate WF. The table 103 is configured to be rotated by a drive mechanism such as a motor, not illustrated. A polishing pad 105 is affixed to the upper surface of the table 103. The CMP unit includes a slurry supply nozzle 114 configured to supply a slurry onto the polishing pad 105. The planarizing apparatus 10 illustrated in FIG. 11 includes a holding head 106 configured to hold the substrate WF. The holding head 106 is configured to be rotated. The substrate WF is supported on a lower surface of the holding head 106 through vacuum chuck. The holding head 106 is configured to move in a direction normal to surfaces of the surface roughening pad 104 and the polishing pad 105. The holding head 106 is configured to move between and over the table 102 of the surface roughening unit 100 and the table 103 of the polishing unit 200 within planes of the tables 102, 103. Consequently, the surface roughening unit 100 and the polishing unit 200 share an arm 109 and the holding head 106. The surface roughening unit 100 can roughen the substrate WF by not only supplying a liquid containing roughening particles onto the surface roughening pad 104 by use of a roughening particle supply nozzle 110 but also forcing the substrate WF against the surface roughening pad 104 by use of the holding head 106, and moving the holding head 106 within the plane of the table 102 while rotating the table 102 and the holding head 106 individually. In addition, the polishing unit 200 can polish the substrate WF by not only supplying a slurry onto the polishing pad 105 by use of the slurry supply nozzle 114 but also pressing the substrate WF against the polishing pad 105 by use of the holding head 106, and moving the holding head 106 within the plane of the table 103 while rotating the table 103 and the holding head 106 individually. Although not illustrated, a cleaning liquid supply nozzle configured to clean the surface roughening pad 104 and the polishing pad 105 and a conditioner may be installed on the surface roughening unit 100 and the polishing unit 200. In this way, a transportation of the substrate WF is omitted by providing the surface roughening unit 100 and the polishing unit 200 in the same housing, whereby the processing speed is increased.

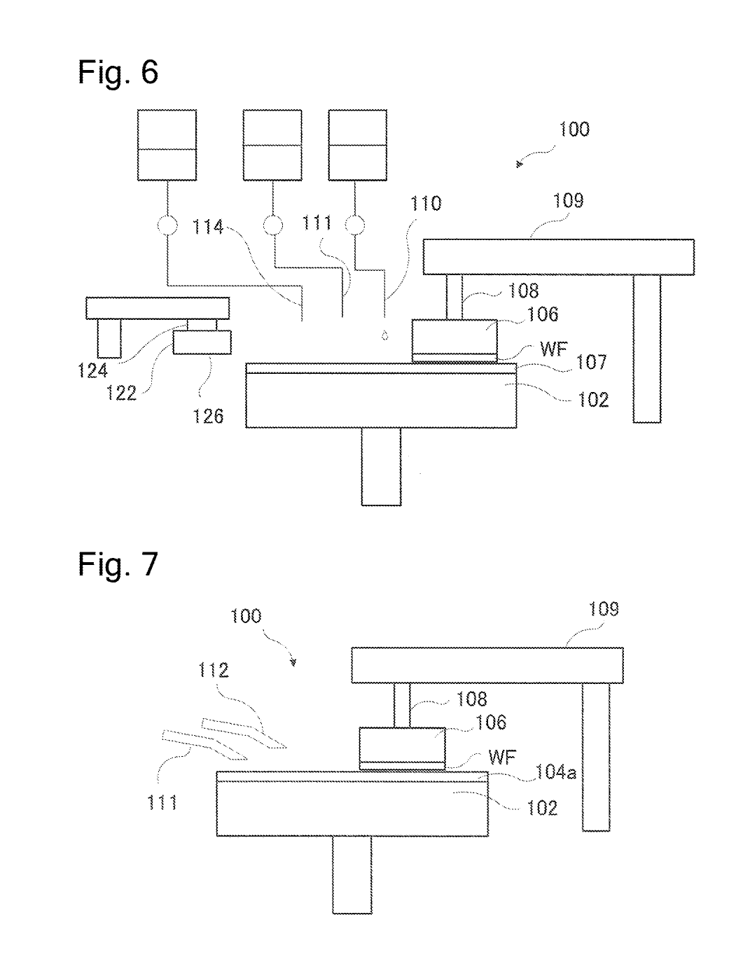

FIG. 6 is a side view schematically illustrating a planarizing apparatus 10 according to an embodiment. In the planarizing apparatus 10 illustrated in FIG. 6, a substrate WF can be surface roughened and then polished on the same pad 107 on the same table 102. The embodiment illustrated in FIG. 6 functions as a surface roughening unit 100, as well as a polishing unit 200. In the illustrated embodiment, a table 102 having a flat upper surface is provided. The table 102 is configured to be rotated by a drive mechanism such as a motor, not illustrated. A pad 107 is affixed on an upper surface of the table 102. The pad 107 functions as a roughening pad and a polishing pad. In the embodiment illustrated in FIG. 6, the pad 107 is larger in dimension than a substrate WF to be surface roughened and polished. In the embodiment illustrated in FIG. 6, a holding head 106 is provided which is configured to hold the substrate WF. The holding head 106 is coupled to a rotatable shaft 108. The shaft 108 can be rotated together with the holding head 106 by a drive mechanism, not illustrated. The substrate WF is supported on a lower surface of the holding head 106 through vacuum chuck. The holding head 106 is configured to move in a direction normal to a surface of the pad 107. The holding head 106 is connected to an arm 109 configured to move within a plane of the table 102, for example, in a radial direction of the table 102. The planarizing apparatus 10 according to the illustrated embodiment includes a roughening particle supply nozzle 110 configured to supply a liquid in which roughening particles configured to roughen a surface of the substrate WF are dispersed onto the pad 107 and a cleaning liquid supply nozzle 111 configured to supply a cleaning liquid. In an embodiment, the roughening particle supply nozzle 110 and the cleaning liquid supply nozzle 111 may be configured to supply roughening particles and a cleaning liquid, respectively, to a fixed constant position on the pad 107 on the table 102 or may be configured to move. In addition, the planarizing apparatus 10 of the illustrated embodiment includes a slurry supply nozzle 114 configured to supply a slurry onto the pad 107. In an embodiment, the slurry supply nozzle 114 may be configured to supply a slurry to a fixed constant position on the pad 107 on the table 102 or may be configured to move. Processes of planarizing the substrate WF according to the embodiment illustrated in FIG. 6 will be described. Firstly, with the liquid containing roughening particles supplied to the pad 107 by the roughening particle supply nozzle 110, the substrate WF held by the holding head 106 is pressed against the pad 107, and the substrate WF and the pad 107 are moved relatively, whereby a target processing surface of the substrate WF is roughened. Next, the liquid containing roughening particles which remains on the target processing surface of the substrate WF and the pad 107 and process products generated by the surface roughening are removed by supplying a cleaning liquid by the cleaning liquid supply nozzle 111. Thereafter, with the substrate WF withdrawn from the pad 107, the pad 107 is conditioned by a conditioner 120. This conditioning step may be carried out at the same time as the target processing surface of the substrate WF and the pad 107 are cleaned. Thereafter, with a CMP slurry supplied to the pad 107 by the slurry supply nozzle 114, the substrate WF held by the holding head 106 is pressed against the pad 107, and the substrate WF and the pad 107 are moved relatively, whereby the target processing surface of the substrate WF is planarized. In this way, by carrying out the surface roughening and the CMP on the same unit, a transport of the substrate WF is omitted to thereby increase the processing speed.

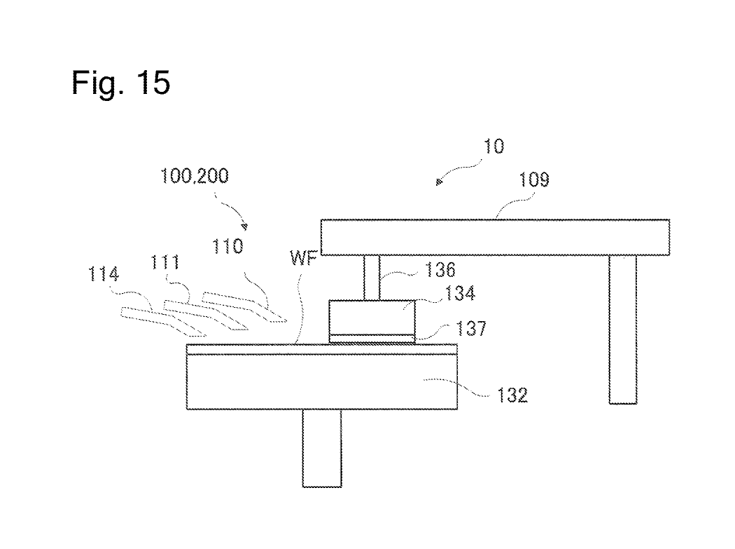

FIG. 15 is a side view schematically illustrating a planarizing apparatus 10 according to an embodiment. In the planarizing apparatus 10 illustrated in FIG. 6, the substrate WF supported on the table 132 can be surface roughened and then polished by use of the same pad 137. In the embodiment illustrated in FIG. 15, a surface roughening unit 100 functions as a polishing unit 200 or vice versa. In the embodiment illustrated in FIG. 15, the planarizing apparatus 10 includes a table 132 having a flat upper surface. The table 132 is configured to be rotated by a motor, not illustrated. A substrate WF is configured to be fixed to the upper surface of the table 132 through vacuum chuck or the like. The planarizing apparatus 10 according to the embodiment illustrated in FIG. 15 includes a head 134. The head 134 is coupled to a rotatable shaft 136. The shaft 136 can be rotated together with the head 134 by a drive mechanism, not illustrated. A pad 137 is attached to a lower surface of the head 134. The shaft 136 is connected to an arm 109 which can oscillate. In the embodiment illustrated in FIG. 15, the pad 137 is smaller in dimension than the substrate WF which is surface roughened and polished. The head 134 is configured to move in a direction normal to a surface of the substrate WF on the table 132. The head 134 is configured to be moved within a plane of the table 132, for example, in a radial direction of the table 132 by the arm 109. In the illustrated embodiment, the planarizing apparatus 10 includes a roughening particle supply nozzle 110. In the illustrated embodiment, the planarizing apparatus 10 includes the roughening particle supply nozzle 110 configured to supply a liquid in which roughening particles configured to roughen the surface of the substrate WF are dispersed onto the substrate WF and a cleaning liquid supply nozzle 111 configured to supply a cleaning liquid. In an embodiment, the roughening particle supply nozzle 110 and the cleaning liquid supply nozzle 111 may be configured to supply roughening particles and the cleaning liquid, respectively, to a fixed constant position on the substrate WF on the table 132 or may be configured to move. In addition, the planarizing apparatus 10 of the illustrated embodiment includes a slurry supply nozzle 114 configured to supply a slurry onto the substrate WF. In an embodiment, the slurry supply nozzle 114 may be configured to supply the slurry to the fixed constant position on the substrate WF on the table 132 or may be configured to move. Processes of planarizing the substrate WF according to the embodiment illustrated in FIG. 15 will be described. Firstly, with the liquid containing roughening particles supplied to the substrate WF by the roughening particle supply nozzle 110, the pad 137 held by the surface roughening head 134 is pressed against the substrate WF, and the substrate WF and the pad 137 are moved relatively, whereby a target processing surface of the substrate WF is roughened. Next, the liquid containing roughening particles which remains on the target processing surface of the substrate WF and the pad 137 and process products generated by the surface roughening are removed by supplying the cleaning liquid by the cleaning liquid supply nozzle 111. As this occurs, although not illustrated, the pad 137 may be conditioned by a conditioner 120. Further, with a CMP slurry supplied to the substrate WF by the slurry supply nozzle 114, the pad 137 held by the surface roughening head 134 is pressed against the substrate WF, and the substrate WF and the pad 137 are moved relatively, whereby the target processing surface of the substrate WF is planarized. In this way, by carrying out the surface roughening and the CMP on the same unit, a transport of the substrate WF is omitted to thereby increase the processing speed.

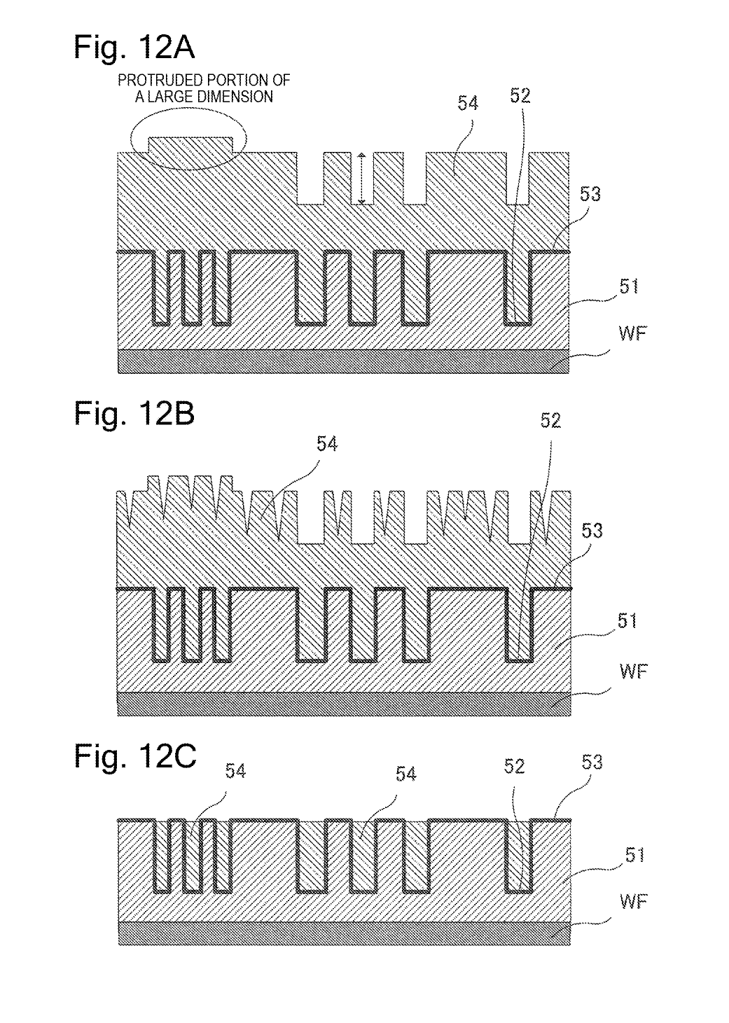

Hereinafter, referring to FIGS. 12 to 14, a planarizing method for planarizing a surface of a substrate according to an embodiment will be described. FIG. 12 is a sectional view illustrating processes of planarizing a substrate in which a Cu layer is formed on a substrate surface including wiring portions. FIG. 12A illustrates a state in which a barrier metal 53 is formed on a substrate WF in which wiring grooves 52 are formed on an insulation film 51 by use of a method such as a PVD, CVD or ALD, further, a Cu seed film is deposited on an upper layer of the barrier metal by use of a PVD method or the like, and thereafter, a Cu layer 54 is formed by use of an electro plating method or the like. Steps are formed on a surface of the Cu layer 54 formed due to wiring structure (width and density of wirings) underneath the formed Cu layer 54 or plating conditions through electro plating. Especially, at a potion where narrow wiring grooves are formed densely, large size of step height (a left-hand side's protruded portion in FIG. 12A) can be formed in electroplating.

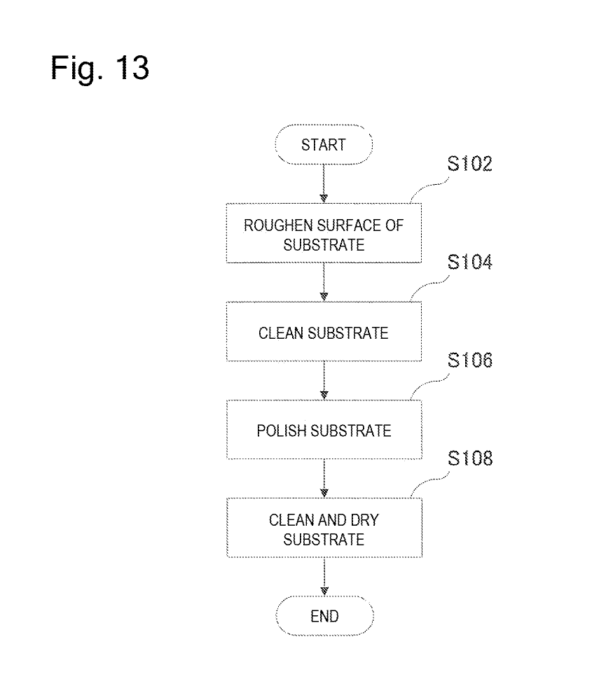

FIG. 13 is a flow chart illustrating a method for planarizing a surface of a substrate according to an embodiment. A case is taken into consideration in which a target processing surface of a substrate WF which is in a state illustrated in FIG. 12A is planarized. In this embodiment, firstly, the surface of the substrate WF is roughened (S102). The target processing surface of the substrate WF can be roughened by use of an arbitrary one of the surface roughening units 100 which have been described heretofore. The roughening of the surface of the substrate WF is intended to reduce a dimension of a large protruded portion formed on the surface of the substrate WF, and therefore, the protruded portion formed on the surface of the substrate WF is preferably roughened for preference. A height of an unevenness formed on the roughened surface of the substrate WF can be determined according to a height of an initial step height formed on the substrate WF to be surface roughened. For example, a height of an unevenness formed as a result of surface roughening the substrate WF can be 80% or smaller of a largest initial step formed on the substrate WF. Alternatively, the height of the unevenness may be 80% or smaller of an average of initial steps. For example, for a largest initial step of 1.0 μm, a height of an unevenness formed as a result of roughening the surface of the substrate WF is preferably 0.8 μm or smaller. This is because since the step height reduction ratio in a general CMP is around 80%, when an unevenness whose height is larger than 80% of initial step height is formed as a result of roughening the surface of the substrate WF, there is a risk that the unevenness cannot be polished away thoroughly in the following polishing step. An average pitch of an unevenness formed as a result of roughening the surface of the substrate (an average of distances between adjacent recessed portions or protruded portions) is desirably 100 μm or smaller. This is because since a step height reduction in the CMP largely depends on a width of an unevenness, with the average pitch being larger than 100 μm, the step height reduction ratio is decreased remarkably. The size and type of roughening particles for use in roughening the surface of the substrate WF, the contact pressure between the surface roughening pads 104, 138 and the substrate WF, and the surface roughening time are selected as required so that a desired surface roughening is achieved. In general, hard roughening particles are used when a target layer to be surface roughened is hard, or when attempting to form a large unevenness as a result of surface roughening, relatively large size of roughening particles are used. In addition, when initial step height formed on the surface of the substrate WF is small, the concentration of roughening particles may be reduced, a supply amount of roughening particles may be reduced, or roughening particles are supplied intermittently. Further, when a thickness of a film to be surface roughened is extremely thin or small, or when a fragile material such as a Low-k material is used, it is concerned that an unevenness formed as a result of surface roughening should become too large. In such a case, a protective film may be formed on the surface of the substrate WF before the substrate WF is surface roughened, whereafter the substrate WF is surface roughened. Such a protective film can be formed by, for example, spraying an organic-based solvent such as a resist or through spin coating. FIG. 12B is a sectional view illustrating the surface roughened substrate WF.

As illustrated in FIG. 13, when the substrate WF has been surface roughened, then, the substrate WF is cleaned (S104). In the event that the substrate WF is not cleaned after it has been surface roughened, roughening particles used to surface roughen the substrate WF remain, causing a risk of scratch on the substrate WF in the following polishing step. However, the cleaning step may be omitted unless the cleaning of the substrate WF is necessary after it has been surface roughened. For example, in the case where roughening particles are the same in type and particle size as particles contained in a slurry for use in the following polishing step, since there are little risk that the roughening particles cause a scratch on the substrate WF in the polishing step, the cleaning step may be omitted.

Next, the substrate WF, which has been surface roughened and cleaned, is polished (S106). The substrate WF can be polished through CMP or the like. The substrate WF can be polished by an arbitrary CMP device. Since the surface of the substrate WF has been roughened before it is polished, no protruded portion of a large dimension exists, a problem with decrease of removal rate occurring at a protruded portion of a large dimension can be eliminated or mitigated. FIG. 12C is a sectional view illustrating the substrate which has been surface roughened and then polished. Here, since the initial steps illustrated in FIG. 12A which are caused due to the wiring structures (the widths and densities of wirings) in the layer underneath the Cu layer 54 or plating conditions through electro plating are eliminated uniformly, dishing and erosion are mitigated.

With the substrate WF being polished completely, the substrate WF is cleaned and is then dried (S108). When the substrate WF has been planarized completely in the way described above, the substrate WF is returned to the cassette 24 (FIG. 2), and the substrate WF is then transported to the following step.

FIG. 14 is a flow chart illustrating a method for planarizing a surface of a substrate. In the planarizing method of this embodiment, firstly, initial steps formed on a surface of a substrate WF to be planarized are measured (S202). Although an arbitrary measuring method can be used, for example, a method is adopted in which shapes of steps are measured directly using a laser microscope (of a confocal form) or a phase shift interference form or are obtained indirectly based on a difference in film thicknesses measured by making use of film thickness measurement. Next, it is determined whether or not the measured steps are smaller than a target value (S204). In relation to this measurement, a measuring module may be provided within the planarizing apparatus for measurement, or the measurement may be made outside the planarizing apparatus. The target value can be 100 nm as an average value or a maximum value. When the initial steps of the substrate WF are the target value or larger, conditions of the substrate WF are determined based on the height and pitch of the step shapes which are obtained from a difference between the target value and the current value, and thereafter, a target processing surface of the substrate WF is roughened, and the roughened target processing surface of the substrate WF being thereafter polished to be planarized (S206 to S212). As this occurs, although not illustrated, a step of forming a protective film on the surface of the substrate WF which can prevent a large unevenness, compared with the initial steps, from being produced in the step of surface roughening may be inserted as a pre-treatment before the surface of the substrate WF is roughened. As has been described above, the protective film can be formed by spraying an organic-based solvent such as a resist or through spin coating. Steps from surface roughening of the substrate to planarization of the roughened target processing surface by polishing are the same as steps S102 to S108 in FIG. 13. When the initial step height on the substrate WF are smaller than the target value, firstly, the substrate WF is polished down to a predetermined residual film thickness (S214). The substrate WF can be polished by a polishing unit 200 such as, for example, an arbitrary CMP device. After the substrate WF has been polished down to the predetermined residual film thickness by the polishing unit 200, the substrate WF is cleaned and dried as required. Thereafter, the remained step height on the surface of the substrate WF are measured again (S216), and it is judged whether or not the measured step height is the target value or larger (S218). For example, the target value can be 10 nm as an average value or a maximum value. In the case where the step height on the surface of the substrate WF is smaller than the target value, planarization of the substrate WF is ended. In the case where the step height on the surface of the substrate WF is equal to or larger than the target value, the substrate WF is surface roughened and is then polished (S222 to S226). As this occurs, although not illustrated, a step of forming a protective film on the surface of the substrate WF may be inserted as a pre-treatment before the surface of the substrate WF is roughened. Since the substrate WF has already been plished once, the remained step height on the surface of the substrate WF should be small. Therefore, to insert the protective film is more effective which can prevent to make a large unevenness compared with the initial steps in the step of surface roughening. Such a protective film can be formed by spraying an organic-based solvent such as a resist or through spin coating, as described above.

### REFERENCE SIGNS LIST

10 . . . Planarizing apparatus
51 . . . Insulation film
52 . . . Wiring groove
54 . . . Cu layer
100 . . . Surface roughening unit
102 . . . Table
103 . . . Table
104, 104a . . . Surface roughening pad
105 . . . Polishing pad
107 . . . Pad
106 . . . Holding head
109 . . . Arm
110 . . . Roughening particles supply nozzle
111 . . . Cleaning liquid supply nozzle
112 . . . Liquid supply nozzle
113 . . . Cleaning liquid supply nozzle
114 . . . Slurry supply nozzle
115 . . . High-pressure supply nozzle
116 . . . Roughening particles supply tank
120 . . . Conditioner
132 . . . Table
134 . . . Surface roughening head
136 . . . Shaft
137 . . . Pad
138, 138a . . . Surface roughening pad
150 . . . Peltier device
152 . . . Thermometer
154 . . . Fluid passageway
156 . . . Pad contact member
158 . . . Liquid supply mechanism
200 . . . Polishing unit
300 . . . Cleaning unit
30a . . . Transport mechanism
30b . . . Transport mechanism
400 . . . Drying unit
500 . . . Control unit
WF . . . Substrate.

What is claimed is:

1. A planarizing apparatus for planarizing a surface of a substrate, comprising:
a surface roughening unit configured to roughen a target processing surface of the substrate by use of roughening particles; and
a chemical mechanical polishing (CMP) unit configured to polish chemically and mechanically the roughened target processing surface of the substrate.

2. The planarizing apparatus according to claim 1,
wherein the surface roughening unit comprises:
a pad which is larger in dimension than the substrate;
a table configured to hold the pad and capable of moving relative to the substrate;
a substrate holding head configured to hold the substrate with the target processing surface of the substrate directed towards the pad and capable of moving relative to the pad while pressing the substrate against the pad;
a first supply nozzle configured to supply a liquid containing roughening particles to the pad while roughening the target processing surface of the substrate;
a second supply nozzle configured to supply a cleaning liquid for cleaning the substrate and the pad after roughening the target processing surface of the substrate; and
a conditioner configured to condition a surface of the pad.

3. The planarizing apparatus according to claim 1,
wherein the surface roughening unit comprises:
a pad which is larger in dimension than the substrate and which contains roughening particles;
a table configured to hold the pad and capable of moving relative to the substrate;
a substrate holding head configured to hold the substrate with the target processing surface of the substrate directed towards the pad and capable of moving relative to the pad while pressing the substrate against the pad;
a first supply nozzle configured to supply a liquid to the pad while roughening the target processing surface of the substrate;
a second supply nozzle configured to supply a cleaning liquid for cleaning the substrate and the pad after roughening the target processing surface of the substrate; and
a conditioner configured to condition a surface of the pad.

4. The planarizing apparatus according to claim 1,
wherein the surface roughening unit comprises:
a pad which is smaller in dimension than the substrate;
a table configured to hold the substrate and capable of moving relative to the substrate;
a holding head configured to hold the pad with the pad directed towards the substrate and capable of moving relative to the pad while pressing the pad against the substrate;
an arm configured to oscillate the holding head on the substrate in a direction parallel to a plane of the substrate;
a first supply nozzle configured to supply a liquid containing roughening particles to the substrate while roughening the target processing surface of the substrate;
a second supply nozzle configured to supply a cleaning liquid to the substrate after roughening the target processing surface of the substrate; and
a conditioner configured to condition a surface of the pad.

5. The planarizing apparatus according to claim 1,
wherein the surface roughening unit comprises:
a pad which is smaller in dimension than the substrate and which contains roughening particles;
a table configured to hold the substrate and capable of moving relative to the pad;
a holding head configured to hold the pad with the pad directed towards the substrate and capable of moving relative to the substrate while pressing the pad against the substrate;
an arm configured to oscillate the holding head on the substrate in a direction parallel to a plane of the substrate;
a first supply nozzle configured to supply a liquid to the substrate while roughening the target processing surface of the substrate;
a second supply nozzle configured to supply a cleaning liquid for cleaning the substrate and the pad after roughening the target processing surface of the substrate; and
a conditioner configured to condition a surface of the pad.

6. The planarizing apparatus according to claim 1,
wherein the surface roughening unit comprises:
a high-pressure supply nozzle configured to supply a liquid containing the roughening particles towards the substrate under a high pressure;
a table configured to hold the substrate and capable of moving relative to the high-pressure supply nozzle;
an arm configured to oscillate the high-pressure supply nozzle in a direction parallel to a plane of the substrate; and
a supply nozzle configured to supply a cleaning liquid to the substrate after roughening the target processing surface of the substrate.

7. The planarizing apparatus according to claim 2,
wherein the relative movement comprises at least one of a rotational movement, a straight-line movement, a scrolling movement and a combination of the rotational movement and the straight-line movement.

8. A planarizing apparatus for planarizing a surface of a substrate, comprising:
a CMP unit configured to perform Chemical Mechanical Polishing (CMP) of the substrate;
a cleaning unit configured to clean the substrate;
a drying unit configured to dry the substrate; and
a transporting mechanism configured to transport the substrate among the CMP unit, the cleaning unit and the drying unit,
wherein the CMP unit comprises:
a first supply nozzle configured to supply a liquid containing roughening particles; and
a second supply nozzle configured to supply a CMP slurry.

9. The planarizing apparatus according to claim 8,
wherein the CMP unit comprises:
a pad which is larger in dimension than the substrate;
a table configured to hold the pad and capable of moving relative to the substrate;
a substrate holding head configured to hold the substrate with a target processing surface of the substrate directed towards the pad and capable of moving relative to the pad while pressing the substrate against the pad;
a third supply nozzle configured to supply a cleaning liquid to the pad; and
a conditioner configured to condition a surface of the pad,
wherein the first supply nozzle is configured to supply the liquid containing roughening particles to the pad, and
wherein the second supply nozzle is configured to supply the CMP slurry onto the pad.

10. The planarizing apparatus according to claim 8,
wherein the CMP unit comprises:
a pad which is smaller in dimension than the substrate;
a table configured to hold the substrate and capable of moving relative to the pad;
a holding head configured to hold the pad with the pad directed towards the substrate and capable of moving relative to the substrate while pressing the pad against the substrate;
an arm configured to oscillate the holding head on the substrate in a direction parallel to a plane of the substrate;
a third supply nozzle configured to supply a cleaning liquid to the substrate; and
a conditioner configured to condition a surface of the pad,
wherein the first supply nozzle is configured to supply the liquid containing roughening particles to the substrate, and
wherein the second supply nozzle is configured to supply the CMP slurry to the substrate.

11. The planarizing apparatus according to claim 1,
wherein an average particle diameter of the roughening particles is 100 nm or smaller.

12. The planarizing apparatus according to claim 1,
wherein the roughening particles comprise particles of at least one selected from a group of diamond, SiC, CBN, SiO₂, CeO₂, and Al₂O₃.

13. A method for planarizing a substrate, comprising:
a surface roughening step of roughening a target processing surface of the substrate using roughening particles; and
a CMP step of performing Chemical Mechanical Polishing (CMP) of the roughened target processing surface of the substrate.

14. The method according to claim 13,
wherein in the surface roughening step, a height of an unevenness formed on the target processing surface of the substrate as a result of roughening the target processing surface is 80% or smaller of a largest initial step height existing on the target processing surface of the substrate before the target processing surface is roughened, and an average pitch of the unevenness formed on the target processing surface of the substrate as a result of roughening the target processing surface is 100 um or smaller.

15. The method according to claim 13,
wherein the surface roughening step comprises:
a step of supplying a liquid containing roughening particles onto a pad which is larger in dimension than the substrate; and a step of moving the pad and the substrate relatively with the pad and the target processing surface of the substrate pressing against each other.

16. The method according to claim 13,
wherein the surface roughening step comprises:
a step of supplying a liquid containing roughening particles onto the substrate; and a step of moving a pad which is smaller in dimension than the substrate and the substrate relatively with the pad pressing against the substrate.

17. The method according to claim 13,
wherein the surface roughening step comprises:
a step of moving a pad, which is larger in dimension than the substrate and to which roughening particles are fixed and the substrate relative to each other with the pad pressing against the substrate.

18. The method according to claim 13,
wherein the surface roughening step comprises:
a step of moving a pad, which is smaller in dimension than the substrate and to which roughening particles are fixed, and the substrate relative to each other with the pad pressing against the substrate; and
a step of oscillating the pad on the substrate in a direction parallel to a plane of the substrate.

19. The method according to claim 13,
wherein the surface roughening step comprises:
a step of supplying a liquid containing roughening particles from a high-pressure supply nozzle towards the substrate under a high pressure;
a step of moving the substrate relative to the high-pressure supply nozzle; and
a step of oscillating the high-pressure supply nozzle in a direction parallel to a plane of the substrate.

20. The method according to claim 13,
wherein an average particle diameter of the roughening particles is 100 um or smaller.

21. The method according to claim 13,
wherein the roughening particles comprise particles of at least one selected from a group of diamond, SiC, CBN, SiO₂, CeO₂, and Al₂O₃.

22. The method according to claim 15,
wherein the relative movement comprises at least one of a rotational movement, a straight-line movement, a scrolling movement and a combination of the rotational movement and the straight-line movement.

23. The method according to claim 13,
wherein the surface roughening step is executed by a surface roughening unit;
wherein the CMP step is executed by a CMP unit; and
comprising a step of transporting the substrate roughened by the surface roughening unit to the CMP unit.

24. The method according to claim 13, comprising:
a step of cleaning the roughened target processing surface of the substrate between the surface roughening step and the CMP step.
